(19) United States
(12) Patent Application Publication
(10) Pub. No.: US 2025/0018510 A1
(43) Pub. Date: Jan. 16, 2025

(54) LASER LIFT-OFF METHOD, METHOD FOR MANUFACTURING RECEPTOR SUBSTRATE, LASER LIFT-OFF APPARATUS, AND PHOTOMASK

(71) Applicant: SHIN-ETSU ENGINEERING CO., LTD., Tokyo (JP)

(72) Inventors: Yoshikazu Ohtani, Annaka-shi (JP); Hiroshi Yamaoka, Yokohama-shi (JP); Masami Kurata, Nerima-ku (JP); Taketo Usami, Shinagawa-ku (JP)

(73) Assignee: SHIN-ETSU ENGINEERING CO., LTD., Tokyo (JP)

(21) Appl. No.: 18/711,848

(22) PCT Filed: Nov. 15, 2022
(86) PCT No.: PCT/JP2022/042366

§ 371 Date: May 20, 2024

(30) Foreign Application Priority Data
Nov. 26, 2021 (JP) 2021-192433

(51) Int. Cl. B23K 37/04; G02B 27/09

(52) U.S. Cl. CPC B23K 37/04; G02B 27/0988

(57) ABSTRACT

The present disclosure provides a laser lift-off method for transferring objects to be transferred from a first substrate provided with the objects to be transferred onto a second substrate by virtue of laser lift-off.

### TECHNICAL FIELD

The present invention relates to a laser lift-off method, a method for manufacturing a receptor substrate, a laser lift-off apparatus, and a photomask.

### BACKGROUND ART

In recent years, nitride semiconductor optical devices have become used for a backlight of a liquid crystal display and a display for signage.

A large number of optical devices are produced, for example, on a sapphire substrate by a semiconductor process. For producing a 4-inch display substrate with LEDs each being a 100 μm or less square, called micro LED, millions of micro LEDs are required. The micro LED, which is a minute device with a length of several tens of micrometers, is utilized after being separated from the sapphire substrate, which is an epitaxial substrate.

The separation is generally performed by bonding a support substrate as a donor precursor substrate to optical devices arranged on a sapphire substrate and separating the optical devices from the sapphire substrate by Laser Lift-OFF (LLO). Thereby, it is possible to obtain a donor substrate on the surface of which a large number of optical devices are provided. Such a method can be applied to not only those related to optical devices but also manufacturing a donor substrate on a surface of which objects to be transferred, such as minute semiconductor devices, are provided with.

Further, objects to be transferred on a donor substrate, for example, can be transferred onto a receptor substrate so as to be arranged pursuant to a circuit board of a product and then can be transferred from the receptor substrate onto another circuit board such as the circuit board of the product by virtue of using a stamping method.

For example, Patent Document 1 proposes a method in which objects to be transferred on a donor substrate are accurately transferred onto a receptor substrate by using irradiation with a laser beam.

A laser lift-off method is a technique to remove objects to be transferred from a substrate (a first substrate) provided with the objects to be transferred by irradiating an interface between the objects to be transferred and the first substrate with a laser beam, and then transfer the removed objects to be transferred onto another substrate (a second substrate).

Such a laser lift-off method is broadly divided into a gap laser lift-off (Gap-LLO) and a contact laser lift-off (Contact-LLO). Hereinafter, these techniques will be described schematically with reference to FIGS. 21 and 22.

In Gap-LLO, first, as shown in FIG. 21(a), a first substrate (for example, a sapphire substrate) 1 provided with objects to be transferred (for example, micro LED chips) 10 and a second substrate (for example, a quartz substrate) 2 provided with an adhesive layer 3 on its surface are placed while facing each other with a space between the objects to be transferred 10 and the adhesive layer 3, namely with a gap. In this state, the interface 11 between each of the objects to be transferred 10 and the first substrate 1 is irradiated with a laser beam 20R from a laser oscillator 110, through a surface opposite to a surface provided with the objects to be transferred 10 of the first substrate 1. In general, entire surface of the interface 11 between each of the objects to be transferred 10 and the first substrate 1 is irradiated with the laser beam 20R in turn.

For example, in case that the first substrate is a sapphire substrate provided with objects to be transferred 10 having a GaN layer on the interface 11, the GaN layer is decomposed (ablation) by the irradiation with the laser beam 20R. When binding force (adhesion force, bonding force, etc.) between the objects to be transferred 10 and the first substrate 1 becomes weak by virtue of the ablation, the objects to be transferred 10 come off from the first substrate 1. Further, the decomposition of the GaN layer generates a gas (for example, nitrogen gas). The removed objects to be transferred 10 are imparted with a propulsion force to the second substrate 2 by virtue of the pressure of this gas, move in a space between the first substrate 1 and the second substrate 2, and arrive at the adhesive layer 3 on the second substrate 2. In this way, the objects to be transferred 10 is transferred onto the second substrate 2.

Next, as shown in FIG. 21(b), the first substrate 1 is removed. Thus, the transfer of the objects to be transferred 10 from the substrate 1 to the substrate 2 is completed.

In Contact-LLO, first, the process is the same as Gap-LLO, except that a first substrate 1 provided with objects to be transferred 10 and a second substrate 2 provided with an adhesive layer 3 on its surface are placed while facing and contacting the objects to be transferred 10 and the adhesive layer 3 as shown in FIG. 22(a). By removing the first substrate as shown in FIG. 22(b) after irradiation with the laser beam 20R, the transfer of the objects to be transferred 10 from the substrate 1 to the substrate 2 is completed.

### CITATION LIST

### Patent Literature

Patent Document 1: JP 2020-4478 A

### SUMMARY OF INVENTION

### Technical Problem

Conventionally, due to the transfer by Gap-LLO, objects to be transferred were sometimes broken. Also, in the transfer by Contact-LLO, chipping in objects to be transferred sometimes occurred.

The present invention was made for solving the above problem. An object of the present invention is to provide a laser lift-off method that can prevent damages of objects to be transferred during transfer, a method for manufacturing a receptor substrate that can manufacture a receptor substrate provided with objects to be transferred having no damage, a laser lift-off apparatus that can prevent occurrence of damage of objects to be transferred during transfer, and a photomask used for laser lift-off that can reduce occurrence of damage to objects to be transferred during transfer.

### Solution to Problem

To solving the above problem, the present invention provides a laser lift-off method for transferring objects to be transferred from a first substrate provided with the objects to be transferred onto a second substrate by virtue of laser lift-off, comprising
an at-once transferring step in which the objects to be transferred are removed from the first substrate by irradiating interfaces between the objects to be transferred and the first substrate at once with a laser beam, and transferred at once onto the second substrate,
wherein, in the at-once transferring step, only a portion of an interface between each of the objects to be transferred and the first substrate is irradiated with the laser beam.

Here, “only a portion of an interface . . . is irradiated with the laser beam” means that irradiating each interface with the laser beam is performed on a portion of each interface. That is, irradiating each interface with the laser beam only have to be performed on a portion of each interface, at the same time as the irradiating an area having no objects to be transferred may be irradiated with the laser beam. Accordingly, the present invention also encompasses an embodiment, where, as shown in FIGS. 4, 5 and 6 which will be described later, an area with no objects to be transferred, such as an area between adjacent objects to be transferred is also irradiated with the laser beam.

In an at-once transferring step, by irradiating a portion (also referred to as “partial irradiation” hereafter) of interface between each of objects to be transferred and a first substrate with the laser beam, it is possible to reduce an impact generated during laser lift-off and reduce occurrence of damage such as a cracking and a chipping of the objects to be transferred in the transfer.

It is preferable that the method further includes, before the at-once transferring step, a preliminary irradiation step in which the interface between each of the objects to be transferred and the first substrate is irradiated with laser beam having energy, which is lower than that in the at-once transferring step and not enough to remove the objects to be transferred from the first substrate.

By preforming such a preliminary irradiation step, in the at-once transferring step, it is possible to further reduce an impact to the objects to be transferred and prevent positional deviation of objects to be transferred. Further, it is also possible to prevent the occurrence of cleavage and thus reduce the generation of residues in the at-once transferring step when a material having a crystal structure such as a GaN layer as an ablation layer is used.

In this event, it is particularly preferable that in the preliminary irradiation step, only a portion of the interface between each of the objects to be transferred and the first substrate is irradiated with the laser beam.

By performing a partial irradiation also in the preliminary irradiation step, it is possible to further prevent occurrence of cleavage and consequently reduce generation of residues when a material having a crystal structure such as a GaN layer as an ablation layer is used.

For example, the preliminary irradiation step can be performed 1 to 4 times.

The number of times to perform the preliminary irradiation step is not particularly limited, but repeating of the step makes it easy to control an impact on objects to be transferred during laser lift-off while appropriately keeping the speed of the laser lift-off.

For example, it is preferable that in each of the preliminary irradiation step and the at-once transferring step, the irradiation with the laser beam is performed so that an irradiated area with the laser beam is 10 to 60% of an area of the interface between each of the objects to be transferred and the first substrate.

When an irradiated area by the partial irradiation in each of the preliminary irradiation step and the at-once transferring step is within the range of 10 to 60% of the area of the interface between each of the objects to be transferred and the first substrate, it is possible to efficiently transfer the objects to be transferred from the first substrate to the second substrate and give a margin for irradiation error with the laser beam.

Irradiated areas with the laser beam are preferably set to be different between the preliminary irradiation step and the at-once transferring step.

By making the irradiated areas different between the preliminary irradiation step and the at-once transferring step, it is possible to reduce occurrence of non-irradiation area between the objects to be transferred and the first substrate and reduce the occurrence of cleavage when a material having a crystal structure such as a GaN layer as an ablation layer is used.

It is preferable that the preliminary irradiation step and the at-once transferring step are performed so that overlapping of the irradiated areas does not exist, or so that overlapping of the irradiated areas is 10% or less of an area of the interface between each of the objects to be transferred and the first substrate.

The irradiated area of in the preliminary irradiation step and that of the at-once transferring step may be overlapped each other. By making overlapping of the irradiation areas 10% or less, it is possible to suppress excessive deterioration of the objects to be transferred and give a margin for irradiation error of the laser beam.

As a total sum of the preliminary irradiation step and the at-once transferring step, the irradiated areas can be 40 to 100% of an area of the interface between each of the objects to be transferred and the first substrate.

By irradiating 40% or more of an area of the interface between each of the objects to be transferred and the first substrate as the total sum of the preliminary irradiation step and the at-once transferring step, transfer of objects can be performed more efficiently. Further, the entire area, i.e. 100%, of the interface between each of the objects to be transferred and the first substrate may be irradiated with the laser beam, if it is the total sum of the preliminary irradiation step and the at-once transferring step.

For example, laser outputs may be set to be different between the preliminary irradiation step and the at-once transferring step.

The energy of the laser beam for irradiation in the preliminary irradiation step can be lower than that in the at-once transferring step by, for example, making laser outputs different between the preliminary irradiation step and the at-once transferring step.

Alternately, a photomask containing a first part having a first laser transmissivity and a second part having a second laser transmissivity being lower than the first laser transmissivity may be provided, in the preliminary irradiation step, irradiation with the laser beam may be performed through the second part of the photomask, and in the at-once transferring step, the irradiation with the laser beam may be performed through the first part of the photomask.

By this means, laser outputs do not have to be different between the preliminary irradiation step and the at-once transferring step, and thus it is advantageous for mass production.

In the at-once transferring step, irradiation with the laser beam is preferably performed so that an irradiated area with the laser beam is 40 to 90% of an area of the interface between each of the objects to be transferred and the first substrate.

When the laser-irradiated area in the at-once transferring step is within the above range, it is possible to reduce occurrence of damage to objects to be transferred while keeping a transfer efficiency.

In the at-once transferring step, irradiation with the laser beam may be performed so that laser-irradiated portions are formed plurally in the interface between each of the objects to be transferred and the first substrate.

A form of partial irradiation is not particularly limited, but for example, laser-irradiated portions may be formed plurally.

In this event, for example, in the at-once transferring step, the irradiation with the laser beam can be performed so that the laser-irradiated portions have at least one shape selected from the group consisting of a circular shape, an elliptic shape, and a polygonal shape.

The shape of the laser-irradiated portions are not particularly limited, but, for example, it can be a circular shape, an elliptic shape, or a polygonal shape.

Alternatively, in the at-once transferring step, the irradiation with the laser beam can be performed so that the laser-irradiated portions have a line shape.

The laser-irradiated portions may be a line shape.

For example, in the at-once transferring step, the laser-irradiated portions can have a rectangular shape or a line shape, and the irradiation with the laser beam can be performed so that a longitudinal direction of the laser-irradiated portions nearly coincides with a longitudinal direction of the objects to be transferred.

Alternately, in the at-once transferring step, the laser-irradiated portions may have a rectangular shape or a line shape, and the irradiation with the laser beam may be performed so that a longitudinal direction of the laser-irradiated portions nearly coincides with a short-length direction of the objects to be transferred.

Alternately, in the at-once transferring step, the laser-irradiated portions may have a rectangular shape or a line shape, and the irradiation with the laser beam may be performed so that the laser-irradiated portions are made to lie on adjacent objects to be transferred.

As described above, the arrangement of the plurality of laser-irradiated portions with respect to the objects to be transferred is not particularly limited.

In the at-once transferring step, irradiation with the laser beam can be performed so that non-irradiated portions where irradiation with the laser beam is not performed are formed plurally in the interface between each of the objects to be transferred and the first substrate.

A partial irradiation may be performed so that a plurality of non-irradiated portions are formed.

In this event, for example, in the at-once transferring step, the irradiation with the laser beam can be performed so that the non-irradiated portions have at least one shape selected from the group consisting of a circular shape, an elliptic shape, and a polygonal shape.

The shape of the non-irradiated portions is not particularly limited, but it can be, for example, a circular shape, an elliptic shape, or a polygonal shape.

Alternatively, in the at-once transferring step, the laser beam may be irradiated so that the non-irradiated portions have a line shape.

The non-irradiated portions may be a line shape.

For example, in the at-once transferring step, the non-irradiated portions can have a rectangular shape or a line shape, and the irradiation with the laser beam can be performed so that a longitudinal direction of the non-irradiated portions nearly coincides with a longitudinal direction of the objects to be transferred.

Alternatively, in the at-once transferring step, the non-irradiated portions may have a rectangular shape or a line shape, and the irradiation with the laser beam may be performed so that a longitudinal direction of the non-irradiated portions nearly coincides with a short-length direction of the objects to be transferred.

Alternatively, in the at-once transferring step, the non-irradiated portions may have a rectangular shape or a line shape, and the irradiation with the laser beam may be performed so that the non-irradiated portions are made to lie on adjacent objects to be transferred.

As described above, the arrangement of the plurality of non-irradiated portions with respect to the objects to be transferred is not particularly limited.

For example, as the objects to be transferred, the objects selected from the group consisting of semiconductor chips, LED chips, resin material films, and inorganic films can be transferred.

In the present invention, the objects to be transferred are not particularly limited, but can be these above, for example.

Furthermore, the present invention provides a method for manufacturing a receptor substrate provided with objects to be transferred, the method comprising:
a step of providing a donor substrate provided with the objects to be transferred and a receptor precursor substrate; and
a step of obtaining receptor substrate by transferring the objects to be transferred from the donor substrate onto the receptor precursor substrate by virtue of laser lift-off, wherein
in the step of obtaining the receptor substrate, by virtue of the laser lift-off method of the present invention, the objects to be transferred are subjected to laser lift-off from the donor substrate as the first substrate onto the receptor precursor substrate as the second substrate.

According to the method for manufacturing a receptor substrate of the present invention, the receptor substrate can be obtained through transferring the objects to be transferred according to the laser lift-off method of the present invention; and thus a receptor substrate provided with objects to be transferred having no damage can be manufactured. Further, it is possible to improve manufacturing yield of a receptor substrate.

Further, the present invention provides a laser lift-off apparatus for transferring objects to be transferred from a first substrate provided with the objects to be transferred onto a second substrate by virtue of laser lift-off, the device comprising:
a laser oscillator;
a stage for supporting the first substrate and the second substrate while facing each other; and
a photomask provided in an optical path between the laser oscillator and the stage,
wherein the laser oscillator, the photomask, and the stage are configured to irradiate interfaces between the objects to be transferred and the first substrate with a laser beam from the laser oscillator at once, and
the photomask has a pattern for shaping the laser beam from the laser oscillator into such a shape that only a portion of an interface between each of the objects to be transferred and the first substrate is irradiated with the laser beam.

The laser lift-off device of the present invention can perform a partial irradiation of each of objects to be transferred when objects to be transferred are transferred at once onto the second substrate by virtue of laser lift-off. By virtue of this, it is possible to reduce an impact generated during laser lift-off and reduce occurrence of damage such as a cracking and a chipping of objects to be transferred in being transferred.

The laser lift-off apparatus is preferably further configured to be able to switch energy of the laser beam for irradiating the interfaces between the objects to be transferred and the first substrate with the laser beam, between energy not enough to remove the objects to be transferred from the first substrate and energy enough to remove the objects to be transferred from the first substrate.

By using such an apparatus, partial irradiation can be performed in a plurality of stages, and an impact on the objects to be transferred can further be reduced when objects to be transferred are transferred onto a second substrate at once by laser lift-off.

Furthermore, it is possible to prevent the occurrence of cleavage and thus reduce the generation of residues when a material having a crystal structure such as a GaN layer as an ablation layer is used for transferring objects to be transferred onto a second substrate at once by laser lift-off.

In this event, for example, the pattern of the photomask can include a first pattern and a second pattern, and
the laser lift-off apparatus can be configured:
so as to be able to irradiate the interfaces between the objects to be transferred and the first substrate with the laser beam through the first pattern at once at the energy enough to remove the objects to be transferred from the first substrate, and
so as to be able to irradiate the interfaces between the objects to be transferred and the first substrate with the laser beam through the second pattern at once at the energy not enough to remove the objects to be transferred from the first substrate.

Such a laser lift-off apparatus can perform partial irradiation in a plurality of stages without changing laser output.

Further, as a photomask of the first embodiment, the present invention provides a photomask used in a laser lift-off method in which objects to be transferred are transferred from a first substrate provided with the objects to be transferred onto a second substrate by virtue of laser lift-off, wherein
the photomask is configured so that an interface between each of the objects to be transferred and the first substrate is irradiated with a received laser beam at once, and
the photomask has a pattern to shape the laser beam so that only a portion of the interface between each of the objects to be transferred and the first substrate is to be an irradiated portion.

Here, “only a proton . . . is to be an irradiated portion” means that an irradiated area with the laser beam of each interface is a portion of each interface. That is, an irradiated area with the laser beam only have to be a portion of each interface, and an area having no objects to be transferred may be included in the pattern as well as the irradiated area.

Accordingly, the present invention also encompasses an embodiment, where, the photomask has a pattern such that, as shown in FIGS. 4, 5 and 6 which will be described later, an area with no objects to be transferred, such as a space between adjunct objects to be transferred, is also irradiated with laser beam.

By using such a photomask, partial irradiation of each of objects to be transferred can be performed when objects to be transferred are transferred at once onto a second substrate by virtue of laser lift-off. By virtue of this, it is possible to reduce an impact generated during laser lift-off and reduce occurrence of damage such as a cracking and a chipping of objects to be transferred in being transferred.

For example, the pattern can be a pattern for shaping the laser beam so that the laser-irradiated portions are formed plurally.

Alternatively, the pattern is a pattern for shaping the laser beam so that non-irradiated portions where irradiation with the laser beam is not performed are formed plurally in the interface between each of the objects to be transferred and the first substrate.

In this way, a pattern of the photomask for the first embodiment of the present invention may be one for forming laser-irradiated portions plurally, or one for forming non-irradiated portions plurally.

The photomask may have a first part on which the pattern is formed and which has a first laser transmissivity, and a second part having a second laser transmissivity being lower than the first laser transmissivity.

A photomask for the first embodiment of the present invention can include 2 or more parts each having a laser transmissivity different from each other. By using such a photomask, it is possible to change energy for irradiating the interface between each of the objects to be transferred and the first substrate without changing laser output.

Further, as a photomask of the second embodiment, the present invention provides a photomask used in a laser lift-off method in which objects to be transferred are transferred by virtue of laser lift-off from a first substrate provided with the objects to be transferred onto a second substrate, comprising:
a first part having a pattern for shaping a shape of a received laser beam into a patterned shape and a first laser transmissivity; and
a second part having a second laser transmissivity being lower than the first laser transmissivity.

By using such a photomask of the second embodiment, it is possible to perform a partial irradiation against each of objects to be transferred when objects to be transferred are transferred at once to a second substrate by laser lift-off. By virtue of this, it is possible to reduce an impact generated during laser lift-off and reduce occurrence of damage such as a cracking and a chipping of objects to be transferred in being transferred.

Further, by using such a photomask, it is possible to change energy of the laser for irradiating an interface between each of the objects to be transferred and the first substrate without changing laser output. Accordingly, it is not essential to incorporate a plurality of laser oscillator into a single laser lift-off apparatus, to perform two times of irradiation with a laser beam by using a single laser lift-off apparatus while changing laser output of its laser oscillator, or to prepare two laser lift-off devices having laser oscillators with different laser outputs, and it becomes possible to perform irradiation with laser beams having multiple laser outputs by a single operation of laser beam.

### Advantageous Effects of Invention

As described above, the inventive laser lift-off method of the present invention can reduce occurrence of damage to objects to be transferred in being transferred.

Further, the method for manufacturing a receptor substrate of the present invention cam manufacture a receptor substrate provided with objects to be transferred having no damage.

Further, by using the laser lift-off apparatus of the present invention, it is possible to implement a laser lift-off method which can reduce occurrence of damage to objects to be transferred in being transferred.

And then, a photomask of the present invention can be a photomask for laser lift-off which can reduce occurrence of damage to objects to be transferred in being transferred.

### BRIEF DESCRIPTION OF DRAWINGS

FIG. 1 is a schematic diagram of the first example of the inventive laser lift-off apparatus;

FIG. 2 is a schematic diagram of the second example of the inventive laser lift-off device;

FIG. 3 is a schematic diagram showing of the at-once transferring step in an example of the inventive laser lift-off method;

FIG. 4 is a schematic diagram showing some forms of partial irradiation in the at-once transferring step of the inventive laser lift-off method;

FIG. 5 is a schematic diagram showing some examples of patterns of a photomask used in the inventive laser lift-off method;

FIG. 6 is a schematic diagram showing some examples of patterns of a photomask used in the inventive laser lift-off method;

FIG. 7 is a schematic diagram showing a preliminary irradiation step and an at-once transferring step in an example of the inventive laser lift-off method;

FIG. 8 is a photograph of a first substrate after objects to be transferred were transferred via the preliminary irradiation step and the at-once transferring step shown in FIG. 7;

FIG. 9 is a photograph of a first substrate after objects to be transferred were transferred via the at-once transferring step shown in FIG. 3;

FIG. 10 is a schematic diagram showing a mechanism of the at-once transferring step shown in FIG. 3;

FIG. 11 is a schematic diagram showing mechanisms of the preliminary irradiation step and the at-once transferring step shown in FIG. 7;

FIG. 12 is a schematic diagram showing the preliminary irradiation step and the at-once transferring step in another example of the inventive laser lift-off;

FIG. 13 is an enlarged view of a part XIII of the photomask shown in FIG. 12.

FIG. 14 is a schematic diagram showing the preliminary irradiation step and the at-once transferring step in another example of the inventive laser lift-off;

FIG. 15 is an enlarged view of a part XV of the photomask shown in FIG. 14.

FIG. 16 is a schematic diagram showing the preliminary irradiation step and the at-once transferring step in another example of the inventive laser lift-off;

FIG. 17 is an enlarged view of a part XII of the photomask shown in FIG. 16.

FIG. 18 is a schematic diagram showing arrangement of objects to be transferred and a photomask in an example of the inventive laser lift-off;

FIG. 19 is a schematic diagram showing an example of laser-irradiated portions after partial irradiation was performed with using the photomask shown in FIG. 18.

FIG. 20 is a photograph of the first substrate after transfer was performed in Example 1;

FIG. 21 is a schematic diagram to describe conventional Gap-LLO;

FIG. 22 is a schematic diagram to describe Contact-LLO.

### DESCRIPTION OF EMBODIMENTS

As described above, there has been desired to develop: a laser lift-off method that can reduce occurrence of damage to objects to be transferred in being transferred; a method for manufacturing a receptor substrate, the method being able to manufacture a receptor substrate provided with objects to be transferred having no damage; a laser lift-off apparatus that can reduce occurrence of damage to objects to be transferred in being transferred; and a photomask for laser lift-off that can reduce occurrence of damage to objects to be transferred in being transferred.

As a result of their diligent study of the above problems, the inventors found that, in transferring objects to be transferred by laser lift-off, by adopting an at-once transferring step where objects to be transferred is transferred at once by virtue of laser lift-off, and, in the at-once transferring step, irradiating only a portion of interface between each of the objects to be transferred and the first substrate with a laser beam, it is possible to prevent positional deviation of objects to be transferred that occurs in the laser lift-off, reduce impact that occurs in the laser lift-off, and reduce occurrence of damage such as a cracking and a chipping to objects to be transferred in being transferred; and then have completed the present invention.

That is, the present invention relates to a laser lift-off method for transferring objects to be transferred from a first substrate provided with the objects to be transferred onto a second substrate by virtue of laser lift-off, comprising
an at-once transferring step in which objects to be transferred are removed from a first substrate by irradiating interfaces between the objects to be transferred and the first substrate at once with a laser beam, and transferred at once onto a second substrate,
wherein, in the at-once transferring step, only a portion of an interface between each of the objects to be transferred and the first substrate is irradiated with the laser beam.

Further, the present invention relates to a method for manufacturing a receptor substrate provided with objects to be transferred, the method comprising:
a step of providing a donor substrate provided with the objects to be transferred and a receptor precursor substrate; and
a step of obtaining receptor substrate by transferring the objects to be transferred from the donor substrate onto the receptor precursor substrate by virtue of laser lift-off, wherein
in the step of obtaining the receptor substrate, by virtue of the laser lift-off method of the present invention, the objects to be transferred are subjected to laser lift-off from the donor substrate as the first substrate onto the receptor precursor substrate as the second substrate.

Further, the present invention relates to a laser lift-off apparatus for transferring objects to be transferred from a first substrate provided with the objects to be transferred onto a second substrate by virtue of laser lift-off, the apparatus comprising:
a laser oscillator;
a stage for supporting the first substrate and the second substrate while facing each other; and
a photomask provided in an optical path between the laser oscillator and the stage,
wherein the laser oscillator, the photomask, and the stage are configured to irradiate interfaces between the objects to be transferred and the first substrate with a laser beam from the laser oscillator at once, and
the photomask has a pattern for shaping a laser beam from the laser oscillator into such a shape that only a portion of an interface between each of the objects to be transferred and the first substrate is irradiated with the laser beam.

Further, the present invention relates to a photomask used in a laser lift-off method in which objects to be transferred are transferred by virtue of laser lift-off from a first substrate provided with the objects to be transferred onto a second substrate, wherein
the photomask is configured so that an interface between each of the objects to be transferred and the first substrate is irradiated at once with a received laser beam, and
the photomask has a pattern to shape the laser beam so that only a portion of the interface between each of the objects to be transferred and the first substrate is to be an irradiated portion.

Further, the present invention relates to a photomask used in a laser lift-off method in which objects to be transferred are transferred by virtue of laser lift-off from a first substrate provided with the objects to be transferred onto a second substrate, comprising:
a first part having a pattern for shaping a shape of a received laser beam into a patterned shape and a first laser transmissivity; and
a second part having a second laser transmissivity being lower than the first laser transmissivity.

Hereinafter, the present invention will be described in detail, but the present invention is not limited thereto.

### [Laser Lift-Off Apparatus]

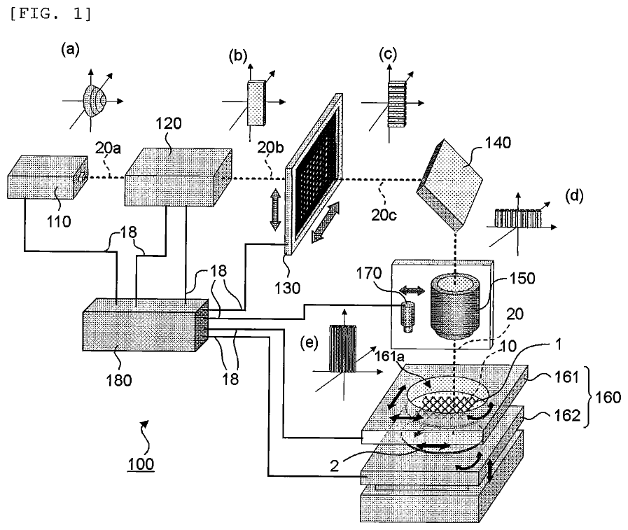

FIG. 1 shows a schematic diagram of the first example of the inventive laser lift-off apparatus.

A laser lift-off apparatus 100 shown in FIG. 1 is an apparatus configured to perform Gap-LLO.

The laser lift-off device 100 includes a laser oscillator 110, a stage 160, and a photomask 130. The laser lift-off device 100 further includes, as optional components, a shaping optical system 120, a reflecting mirror 140, a reduced projection lens 150, an alignment camera 170, and a controller 180.

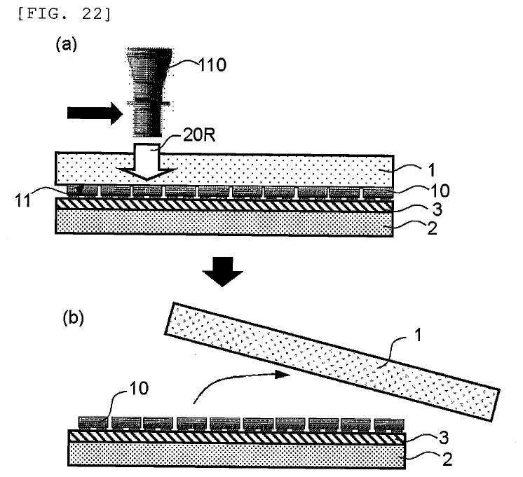

The stage 160 includes an upper stage 161 having an opening 161a and supporting a first substrate 1, and a lower stage 162 supporting a second substrate 2. The first substrate 1 includes a plurality of objects to be transferred 10, similarly to a first substrate 1 shown in FIGS. 21(a) and 22(a). The stage 160 is configured to support the first substrate 1 and the second substrate 2 while facing each other.

The laser oscillator 110 is configured to oscillate a laser beam 20a. In the laser lift-off apparatus 100, the components are arranged so as to form an optical path where: the laser beam 20a emitted from the laser oscillator 110 passes through the shaping optical system 120 to be shaped into a laser beam 20b; the laser beam 20b passes through the photomask 130 where to be shaped into a laser beam 20c; the direction of the laser beam 20c is changed by the reflecting mirror 140; the laser beam 20c passes through the reduced projection lens 150 to become a laser beam 20; the laser beam 20 passes through the opening 161a of the upper stage 161 to reach the first substrate 1. That is, the photomask 130 is provided in an optical path between the laser oscillator 110 and the stage 160.

In the laser lift-off apparatus 100 shown in FIG. 1, the laser oscillator 110, the photomask 130, and the stage 160 (upper stage 161 and lower stage 162) are configured to irradiate interfaces between the objects to be transferred 10 and the first substrate 1 with the laser beam 20 from the laser oscillator 110 at once.

Hereinafter, the optical path of the laser beam emitted from the laser oscillator 110 will be described.

The laser beam 20a emitted from the laser oscillator 110 is, for example, an excimer laser beam.

The shaping optical system 120, which is an optional component, shapes an irradiation shape of the laser beam 20a emitted from the laser oscillator 110, for example, as shown in FIG. 1(a), into a rectangular irradiation shape, for example, as shown in FIG. 1(b), and then the shaped laser beam is emitted as the laser beam 20b. The laser beam 20b having a rectangular irradiation shape can exhibit a uniform irradiation energy density, and has a beam profile exhibiting a top-hat shape, for example. However, laser-shaping by the shaping optical system 120 is not limited thereto.

The photomask 130 is configured to shape the irradiation shape of the incident laser beam 20b into a patterned shape as shown in FIG. 1(c) to emit the shaped laser beam as the laser beam 20c. More specifically, the photomask 130 has a pattern that shapes a laser beam from the laser oscillator 110 into a laser beam having such an irradiation shape that only a portion of the interface between each of the objects to be transferred 10 and the first substrate 1 is irradiated with the laser beam. Further, it can also be said that the photomask 130 is configured to irradiate the interface between each of the objects to be transferred 10 and the first substrate 1 with the received laser beam at once and that the photomask 130 has a pattern for shaping the laser beam so that only a portion of the interface between each of the objects to be transferred 10 and the first substrate 1 becomes the irradiated area.

The photomask 130 may further include a pattern for shaping the laser beam so that an entire area of the interface between each of the objects to be transferred 10 and the first substrate 1 becomes the irradiated area. Other details of the photomask 130 will be described later.

The laser beam 20c emitted from the photomask 130 changes its traveling direction by the reflecting mirror 140 and enters the reduced projection lens 150. The reduced projection lens 150 reduces the irradiation shape of the incident laser beam 20c, for example, from that shown in FIG. 1(d) to that shown in FIG. 1(e), and emits the laser beam as the laser beam 20.

By incorporating the reduced projection lens 150 into the optical path, the energy of the laser beam 20b incident on the photomask 130 can be made smaller than the energy required to remove the objects to be transferred 10 from the first substrate 1. When the reduction magnification of the reduced projection optical lens 150 is N, the energy of the laser beam 20b that the photomask 130 receives is 1/(N²) compared to the energy of the laser beam 20 required to remove the objects to be transferred 10 from the first substrate 1. This can prevent deterioration of the shaping optical system 120 and the photomask 130 due to irradiation with a laser beam, and also reduce thermal drift due to the energy of the laser beam 20b, which can suppress thermal expansion of the photomask 130 and highly accurate transfers can be performed even after prolonged laser lift-off. Furthermore, the influence of particles on the photomask 130 can also be reduced.

The alignment camera 170 and the controller 180 are configured to monitor irradiated areas with the laser beam 20 on the first substrate 1 and to control the laser oscillator 110, the photomask 130, and the stage 160 (upper stage 161 and lower stage 162). The controller 180 can, for example, move the photomask 130 to change the position of the pattern of the photomask 130 with respect to the optical path of the laser beam 20b. Further, the controller 180 can move and/or rotate the upper stage 161 on the same plane to change the position of the first substrate 1, particularly the position of the objects to be transferred 10 with respect to the optical path of the laser beam 20. Further, the controller 180 can move and/or rotate the lower stage 162 on the same plane to change the position of the second substrate 2 with respect to the optical path of the laser beam 20.

Further, the controller 180 can control the laser lift-off apparatus 100 to implement the laser lift-off method of the present invention as described later.

In the laser lift-off apparatus 100 shown in FIG. 1, the laser oscillator 110, the photomask 130, the alignment camera 170, the upper stage 161, and the lower stage 162 are each electrically connected to the controller 180 via a communication line 18.

The laser lift-off apparatus 100 of the present invention is not limited to an apparatus that performs Gap-LLO as shown in FIG. 1, but may also be an apparatus that performs Contact-LLO.

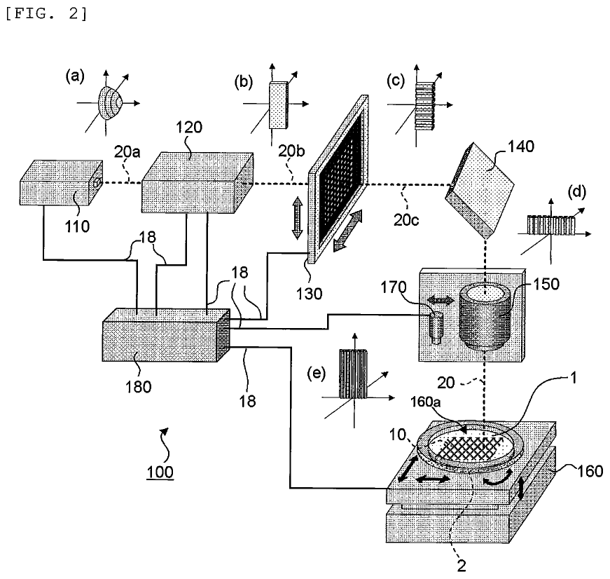

FIG. 2 is a Schematic Diagram of a Second Example of the inventive laser lift-off apparatus. The laser lift-off apparatus 100 shown in FIG. 2 is an apparatus configured to perform Contact-LLO. The laser lift-off apparatus 100 shown in FIG. 2 is the same as the laser lift-off apparatus 100 shown in FIG. 1 except that the stage 160 having an opening 160a supports the first substrate 1 and the second substrate 2 while the objects to be transferred 10 on the first substrate are keeping contact with the second substrate 2.

### [Laser Lift-Off Method]

Hereinafter, as an example of the inventive laser lift-off method, an example using the laser lift-off apparatus 100 shown in FIG. 1 will be described. However, the inventive laser lift-off method is not limited to one performed by using the laser lift-off apparatus 100 shown in FIG. 1, and can also be performed by the laser lift-off apparatus 100 shown in FIG. 2, or other apparatuses.

The inventive laser lift-off method includes an at-once transferring step using partial irradiation, which will be described below with reference to FIG. 3.

FIG. 3(a) is a schematic cross-sectional view showing concept of irradiation with a laser beam in the at-once transfer step in an example of the inventive laser lift-off method. FIG. 3(b) is a diagram showing the positional relationship between a pattern of the photomask and one of objects to be transferred during the irradiation with a laser beam shown in FIG. 3(a).

In this example, a laser beam 20a emitted from the laser oscillator 110 shown in FIG. 1 is shaped into a laser beam 20b by a shaping optical system 120. The laser beam 20b enter into the photomask 130 shown in FIGS. 3(a) and 3(b).

The photomask 130 shown in FIGS. 3(a) and 3(b) includes a laser-transmissive base material 131 and a pattern-forming layer 132 formed on the base material 131. As shown in FIG. 3(b), a pattern 31 including a plurality of openings 132a is formed in the pattern-forming layer 132.

The portion other than the openings 132a of the pattern-forming layer 132 block the laser beam. Therefore, only the components of the laser beam 20b incident on the photomask 130 that passes through the portions corresponding to the openings 132a is transmitted through the photomask 130. As a result, a laser beam (laser beam 20c shown in FIG. 1) having an irradiation shape having a pattern 31 is emitted from the photomask 130. Next, although not shown in FIG. 3, the laser beam 20c enters the reduced projection lens 150 shown in FIG. 1. In the reduced projection lens 150, the laser beam 20c is reduced in size while the irradiation shape maintains the pattern 31 shown in FIG. 3(b) and emitted as the laser beam 20.

The laser beam 20 emitted from the reduced projection lens 150 is incident on the surface of the first base material 1 opposite to the objects to be transferred 10. The laser beam 20 passes through the first base material 1 and reaches the interface 11 between the first base material 1 and objects to be transferred 10.

Here, the term “interface” does not mean a strict boundary surface, but rather a region that is subjected to decomposition or the like by irradiation with a laser beam. Therefore, it can also be referred to as an ablation layer. Specifically, it encompasses: an embodiment in which at least a portion of the side having the objects to be transferred 10 of the first substrate 1 is an ablation layer; an embodiment in which the side having the objects to be transferred 10 on the first substrate 1 has an ablation layer formed; an embodiment in which at least a portion of the side in contact with the first substrate 1 of the objects to be transferred 10 is an ablation layer; an embodiment in which the side in contact with the first substrate 1 of the objects to be transferred 10 has an ablation layer formed; and an embodiment in which an ablation layer is positioned between the first substrate 1 and the objects to be transferred 10. The ablation layer may be a part of the first substrate 1 or a part of the objects to be transferred 10. The ablation layer may be provided separately from the first substrate 1 and the objects to be transferred 10.

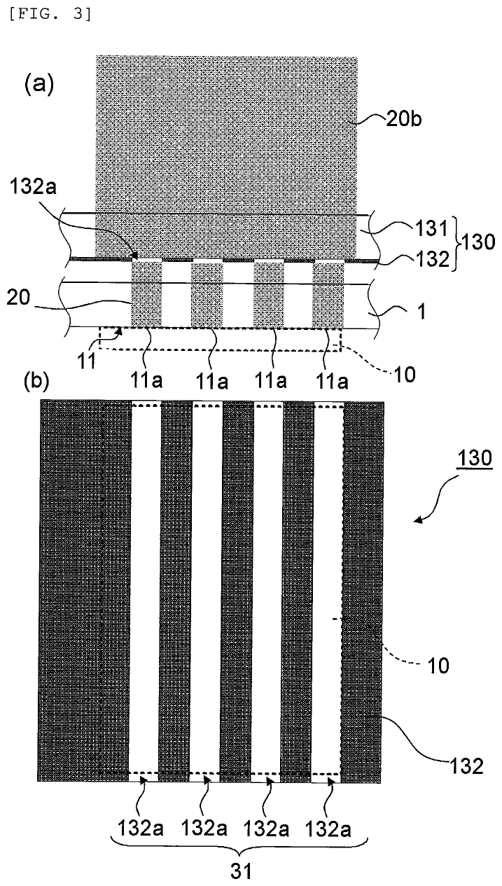

Although FIG. 3 shows only one of objects to be transferred 10, in the inventive laser lift-off method, the interface 11 between the objects to be transferred 10 and the first substrate 1 is irradiated with the laser beam 20 at once by, for example, using a pattern 31 as shown in FIG. 4(a) or 4(b) in the at-once transferring step. However, the objects to be transferred 10 do not necessarily have to be adjacent to each other as shown. For example, the objects to be transferred 10 may be arranged apart from each other without being adjacent to each other.

As described above, the laser beam 20 has an irradiation shape having the pattern 31 of the photomask 130. Therefore, as shown in FIGS. 3(a) and 3(b), the whole area of the interface 11 between each of the objects to be transferred 10 and the first substrate 1 is not irradiated with the laser beam 20, but only portions 11a of the interface 11 is irradiated with the laser beam 20. That is, in the inventive laser lift-off method, in the at-once transferring step, only the portions 11a of the interface 11 between each of the objects to be transferred 10 and the first substrate 1 are irradiated with laser beam 20 (partial irradiation).

In the at-once transferring step, by virtue of such a partial irradiation of the objects to be transferred 10 with the laser beam 20, the objects to be transferred 10 are removed from the first substrate 1.

The energy required for the removal is energy to be able to weaken binding force (for example, adhesion force or joining force) between the objects to be transferred 10 and the first substrate 1, and thus separate the objects to be transferred 10 from the first substrate 1. For example, when there is a GaN layer at the interface between the objects to be transferred 10 and the first substrate 1, it is necessary to decompose (ablate) the GaN layer in order to remove the objects to be transferred 10. The laser energy density required in this case is high. Furthermore, the decomposition of the GaN layer generates nitrogen gas. The pressure of the generated nitrogen gas becomes propulsion force, and the objects to be transferred 10 separated from the first substrate 1 are moved to the second substrate 2. This accomplishes the transfer.

Although GaN is difficult to decompose, it rapidly decomposes when energy exceeds a threshold. Therefore, in the at-once transferring step, as shown in FIG. 22, when whole area of the interface 11 between each of the objects to be transferred 10 and the first substrate 1 is irradiated with the laser beam 20R having energy that can remove the objects to be transferred 10 from the first substrate 1, a large amount of nitrogen gas is rapidly generated and the ejection vector due to the generated gas is too large. By this, the objects to be transferred 10 removed from the first substrate 1 are subjected to excessive pressure or have an excessively high initial velocity, and consequently collide with a surface of the second substrate 2 by a very large ejection vector from the first substrate 1 to the second substrate 2. As a result, the objects to be transferred 10 become easy to crack while transferred from the first substrate 1 to the second substrate 2, or the objects to be transferred 10 become easy to have a cracking and a chipping when they reach the second substrate 2. Furthermore, due to excessive ejection vector, it becomes difficult to control the movement of the objects to be transferred 10 to the second substrate 2, and unintended positional deviation of objects to be transferred becomes easy to occur when the objects to be transferred 10 are transferred to the second substrate 2.

In contrast, in the inventive laser lift-off method, by performing the partial irradiation in the at-once transferring step, wherein only a part of the interface 11 between each of the objects to be transferred 10 and the first substrate 1 is irradiated with the laser beam 10 as described above, the amount of gas generated when the objects to be transferred 10 are removed from the first substrate 1 is reduced, and the pressure that is applied to the objects to be transferred 10 removed from the first substrate 1 can be reduced. As a result, the propulsion force imparted to the objects to be transferred 10 removed from the first substrate 1 can be moderately reduced, and the impact caused by contact between the objects to be transferred 1 and the second substrate 2 can be reduced. Further, the objects to be transferred 10 after being removed can be moved straight from the first substrate 1 to the second substrate 2, and it is possible to perform a lift-off process with high accuracy of transferred position.

As described above with an example in which the GaN layer decomposes during removing the objects to be removed, in the case of full-surface irradiation, the problem that the ejection vector becomes too large as in the above example inevitably arises because the removing by laser lift-off is based on ablation. On the other hand, in the inventive laser lift-off method, because this ejection vector can be kept small by performing partial irradiation in the at-once transferring step, the objects to be transferred 10 can be transferred while preventing damage such as a cracking and a chipping of objects to be transferred 10, regardless of the combination of substrate 1 and objects to be transferred 10. In addition, although the application of partial irradiation to laser lift-off using ablation is described here, also in the case of transfer methods where propulsion force by virtue of other than ablation is imparted to objects to be transferred by irradiation with a laser beam, the propulsion force can be reduced by the partial irradiation with the laser beam, which can lead to improved transfer accuracy.

Furthermore, for example, even in transferring by Contact-LLO using the laser lift-off apparatus 100 shown in FIG. 2, a cracking or a chipping due to the ejection vector becoming too large may occurs similarly to the above, when the entire surface is irradiated. According to the inventive laser lift-off method, even in the Contact-LLO, objects to be transferred 10 can be transferred while preventing damage such a cracking or a chipping of objects to be transferred 10.

Further, when decomposition products are generated by irradiation with a laser beam, the amount of the products generated can be reduced and the subsequent cleaning process can be simplified.

The various modification of the laser lift-off method and laser lift-off apparatus of the present invention can be made. Some embodiments will be described below.

### [Laser-Irradiated Portion and Non-Irradiated Portion]

In the inventive laser lift-off method, only a portion of the interface 11 between each of the objects to be transferred 10 and the first substrate 1 is partially irradiated with the laser beam 20; and thus a laser-irradiated portion where irradiated with the laser beam 20 and a non-irradiated portion where not irradiated with the laser beam 20 are formed.

For example, the portions corresponding to the openings 132a of the pattern 31 of the photomask 130 shown in FIGS. 4(a) and 4(b) are to be the laser-irradiated portions, and the portions corresponding to the non-openings 132b other than the openings 132a of the pattern 31 is to be the non-irradiated portion.

Although the embodiment of partial irradiation is not particularly limited, the irradiation with the laser beam 20 may be performed so that the laser-irradiated portions are formed plurally, as shown in FIGS. 4(a) and 4(b), for example.

The shape of the laser-irradiated portion can be changed as appropriate by, for example, the pattern 31 of the photomask 130.

FIGS. 5(a) to 5(d) schematically show some examples of the pattern of the photomask that can be used to form a plurality of laser-irradiated portions in the present invention.

For example, as shown in FIGS. 5(a) and 5(b), the openings 132a of the photomask 130 can be made in a circular shape. In FIG. 5(a), the openings 132a in a circular shape are arranged in a staggered manner, that is, alternately. In FIG. 5(b), the openings 132a in a circular shape are arranged in a matrix, that is, in rows and columns. The shape of the openings 132a arranged in a staggered pattern or in a matrix is not limited to a circular shape, and may be an elliptic shape, a polygonal shape, or other shapes, or a combination thereof.

FIGS. 5(c) and (d) are examples in which the opening 132a of the photomask 130 is a rectangular shape. In FIG. 5(c), the longitudinal directions of a plurality of rectangular openings 132a nearly coincide with the short-length directions of the objects to be transferred 10. In FIG. 5(d), the longitudinal directions of a plurality of rectangular openings 132a nearly coincide with the longitudinal direction of the objects to be transferred 10. Here, “nearly coincide” means that two straight lines match or the angle between them is 5 degrees or less.

Further, in FIG. 5(c), a plurality of rectangular openings 132a are arranged so as to run over adjacent objects to be transferred 10. By using such a photomask 130, it is possible to perform irradiation with the laser beam 20 so that the laser-irradiated portions are made to lie on the adjacent objects to be transferred 10.

Note that, in examples of the photomask 130 shown in FIGS. 4 and 5, non-opening portion 132b other than the opening portions 132a are continuous. Therefore, by irradiation with a laser beam using such a photomask 130, one continuous non-irradiation region can be formed.

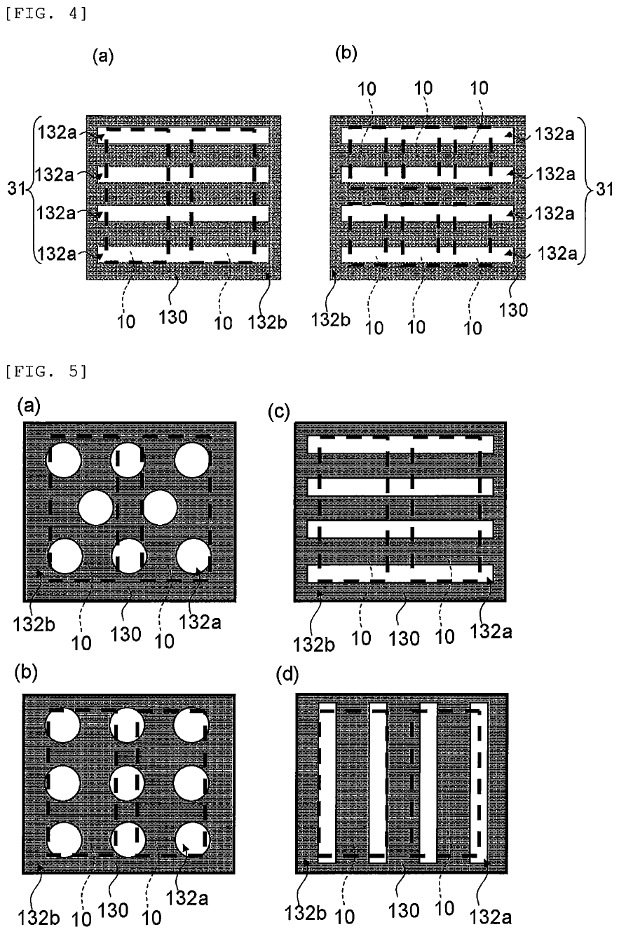

On the other hand, for example, by using photomask 130 shown in FIGS. 6(a) to 6(d) obtained by inverting the pattern of the photomask 130 shown in each example in FIG. 5, irradiation with laser beam 20 can be performed so that a plurality of non-irradiation areas can be formed.

For example, as shown in FIGS. 6(a) and 6(b), the non-opening portions 132b of the photomask 130 can be a circular shape. In FIG. 6(a), the circular non-opening portions 132b are arranged in a staggered manner, that is, alternately. In FIG. 6(b), circular non-opening portions 132b are arranged in a matrix, that is, in rows and columns. The shape of the non-opening portions 132b arranged in a staggered or matrix manner is not limited to a circular shape, and may be an elliptic shape, a polygonal shape, or other shapes, or a combination thereof.

FIGS. 6(c) and (d) are examples in which the non-opening portions 132b of the photomask 130 are rectangular. In FIG. 6(c), the longitudinal directions of the plurality of rectangular non-opening portions 132b nearly coincide with the short-length directions of the objects to be transferred 10. In FIG. 6(d), the longitudinal directions of the plurality of rectangular non-opening portions 132b nearly coincide with the longitudinal directions of the objects to be transferred 10. Here, “nearly coincide” means that two straight lines match or the angle between them is 5 degrees or less.

In FIG. 6(c), a plurality of rectangular non-opening portions 132b are arranged so as to run over adjacent objects to be transferred 10. By using such a photomask 130, it is possible to perform irradiation with the laser beam 20 so that the non-irradiated portions are made to lie on adjacent objects to be transferred.

Note that, the means for forming a plurality of irradiation areas and the means for forming a plurality of non-irradiation areas are not limited to the examples given above.

In addition, in the at-once transferring step, irradiation with the laser beam is preferably performed so that an irradiated area with the laser beam is 40 to 90% of an area of the interface 11 between each of the objects to be transferred 10 and the first substrate 1.

When the area of the laser-irradiated portion in the at-once transferring step is within the above range, occurrence of damage to objects to be transferred 10 can be reduced while keeping transfer efficiency.

### [Multiple Irradiation]

The inventive laser lift-off method preferably includes further, before the at-once transferring step described above, a preliminary irradiation step in which the interface 11 between each of the objects to be transferred 10 and the first substrate 1 is irradiated with laser beam having energy, which is lower than that in the at-once transferring step and not enough to remove the objects to be transferred 10 from the first substrate 1.

By preforming such a preliminary irradiation step, in the at-once transferring step, it is possible to reduce further an impact to the objects to be transferred 10. Further, it is also possible to prevent occurrence of cleavage and generation of residues when a material having a crystal structure such as a GaN layer as an ablation layer is used in the at-once transferring step.

In the preliminary irradiation step, the entire interface 11 between each of the objects to be transferred 10 and the first substrate 1 may be irradiated with the laser beam, but it is particularly preferable that only a portion of the interface 11 is irradiated with the laser beam.

By performing partial irradiation also in the preliminary irradiation step, it is possible to prevent occurrence of cleavage further and consequently occurrence of residues can be reduced when a material having a crystal structure such as a GaN layer as an ablation layer is used.

In the preliminary irradiation step, means to perform the irradiation with the laser beam 20 having energy, which is lower than that in the at-once transferring step and not enough to remove the objects to be transferred 10 from the first substrate 1, is not particularly limited. Hereinafter, this will be described with some examples.

### First Example

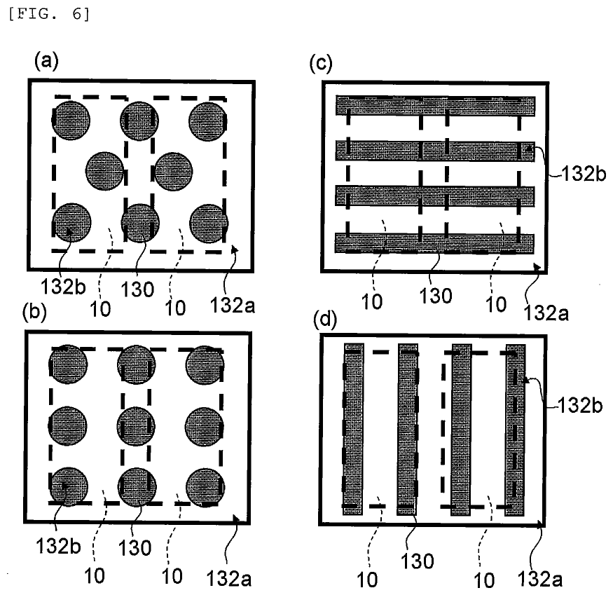

FIG. 7(a) schematically shows a first example of the preliminary irradiation step in an example of the inventive laser lift-off method. Further, FIG. 7(b) shows an example of the at-once transferring step performed after the preliminary irradiation step shown in FIG. 7(a).

In the preliminary irradiation step shown in FIG. 7(a), portions 11b of the interface 11 between each of the objects to be transferred 10 and the first substrate 1 are irradiated with the laser beam 20e having energy, which is lower than that of the laser beam 20 emitted in the at-once transferring step shown in FIG. 7(b) and not enough to remove the objects to be transferred 10 from the first substrate 1.

In this example, as is clear from FIG. 7, in the interface 11, portions 11b that are irradiated with the laser beam 20e in the preliminary irradiation step are different from portions 11a that are irradiated with the laser beam 20 in the at-once transfer step. Such a partial irradiation can be accomplished by use of the photomask 130, for example as shown in FIG. 7, having a second pattern 32 including openings 132c that is different from a pattern (first pattern) 31 including openings 132a, and by performing preliminary irradiation through the second patterns 32.

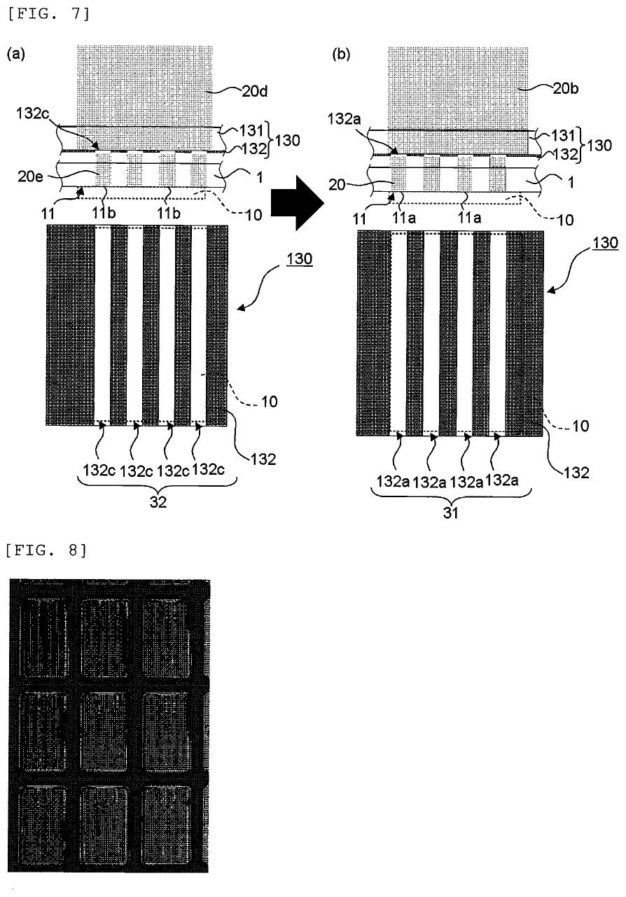

FIG. 8 shows a photograph of the first substrate 1 after the objects to be transferred 10 were transferred thorough the preliminary irradiation step and the at-once transfer step shown in FIG. 7. Further, for comparison, FIG. 9 shows a photograph of the first substrate 1 after the objects to be transferred 10 were transferred thorough the at-once transfer step shown in FIG. 3.

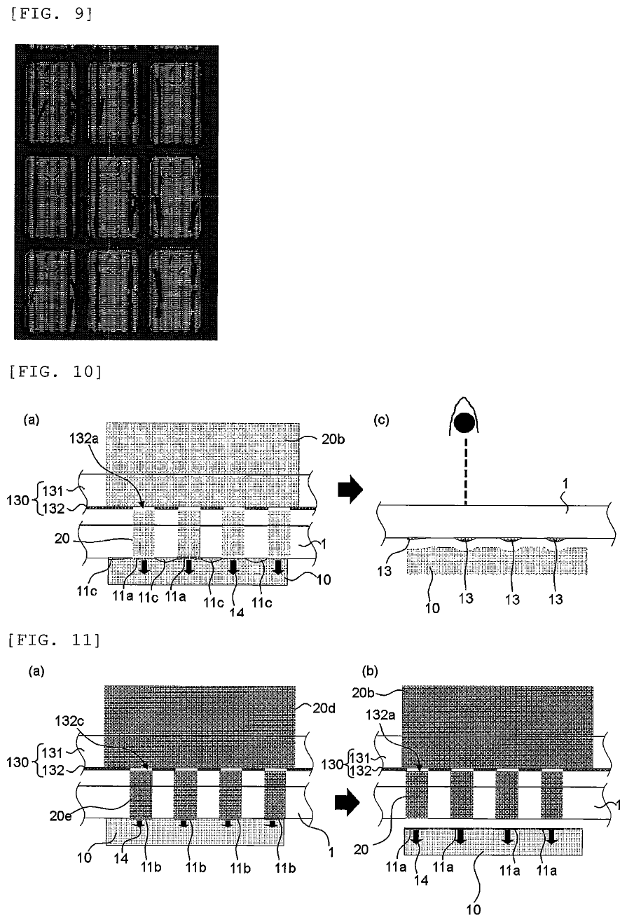

As is clear from the comparison between FIGS. 8 and 9, the first substrate 1 (FIG. 8), of which the objects to be transferred 10 were transferred through the preliminary irradiation step and the at-once transfer step, had no observation of the residues that remained on the first substrate 1 (FIG. 9) for which the preliminary irradiation step was not performed. The reason for this will be described below with reference to FIGS. 10 and 11.

FIG. 10 is a schematic diagram showing the mechanism of the at-once transferring step shown in FIG. 3. FIG. 11 is a schematic diagram showing the mechanism of the preliminary irradiation step and the at-once transferring step shown in FIG. 7.

In the at-once transfer step shown in FIG. 3, as described above, a component (for example, GaN) contained in the portions 11a of the interface 11 between the objects to be transferred 10 and the first substrate 1, is discomposed. Because the energy required to decompose GaN is high, the energy of the laser beam 20 incident on the portions 11a of the interface 11 is about 1.4 J/cm², for example. When the portions 11a of the interface 11 is irradiated with the laser beam 20 having such energy, the portions 11a are portions of a normal removal, but the energy is transmitted to portions adjacent to the portions 11a of the interface 11 also. Further, the nitrogen gas generated by the decomposition of GaN generates a large ejection vector 14, which applies to the portions 11a of the interface 11, and generate stress in the portions adjacent to the portions 11a of the interface 11. As a result, cleavage portions 11c are generated in the portions adjacent to the portions 11a of the interface 11.

The generated cleavage portions 11c remain as a residue 13 on the first substrate 1 and/or on the objects to be transferred 10 when the objects to be transferred 10 are removed from the substrate 1. The black objects shown in FIG. 9 are the residues.

On the other hand, in the preliminary irradiation step shown in FIG. 11(a), the portions 11b of the interface 11 between the objects to be removed 10 and the first substrate 1 are irradiated with the laser beam 20e with energy that is not enough to remove the objects to be transferred 10 from the first substrate 1. In such irradiation with the laser beam, GaN is partially separated in the portions 11b; but the separated portion is very thin; and the first substrate 1 and the objects to be transferred 10 remain loosely bonded.

Furthermore, since the amount of decomposition of GaN is small, the ejection vector 14 is smaller than the ejection vector shown in FIG. 10. Such a preliminary irradiation can prevent the occurrence of the cleavage portions 11c shown in FIG. 10.

In the example shown in FIG. 11, after the preliminary irradiation step shown in FIG. 11(a), the at-once transferring step shown in FIG. 11(b) is performed. In the at-once transfer step, irradiation with the laser beam 20 having energy that can decompose GaN contained in the interface 11 in the same way as in the at-once transfer step shown in FIG. 10 and can remove the objects to be transferred 10 from the first substrate 1, is performed. At this time, the same large ejection vector 14 as shown in FIG. 10 is applied to the portions 11a of the interface 11. Since the very thin delamination is caused in advance by the preliminary irradiation step in the portions 11b adjacent to the portions 11a of the interface 11, it is possible to prevent stress that can cause the cleavage portions 11c from being applied to the portions 11b. As a result, even after the objects to be transferred 10 are removed from the first substrate 1, it is possible to prevent residues as shown in FIG. 9 from remaining as shown in FIG. 8.

In this embodiment, although the residue 13 is derived from a part of the objects to be transferred 10, it is a part of the components for holding the objects to be transferred 10 on the first substrate 1, and thus the function of the objects to be transferred 10 is not significantly affected. Therefore, even if the residue 13 remains on the first substrate 1 or the objects to be transferred 10, this does not mean that the objects to be transferred 10 are damaged.

However, when the residue 13 remains after the transfer and if the objects to be transferred are light emitting devices, there is a risk of uneven light emission or becoming a source of dust. It is advantageous for mass production to suppress the generation of the residue because it becomes necessary to clean the first substrate 1 and the objects to be transferred 10.

Note that, here, a description was made about cleavages that can occur when a material having a crystal structure such as a GaN layer is used as the ablation layer.

On the other hand, the present invention is also effective in an ablation layer in which the occurrence of cleavage does not pose a problem. Specifically, when an organic film such as a polyimide film is used as an ablation layer, cleavage does not occur; but by virtue of performing partial irradiation with a laser beam, the excessive propulsion force that occurs in objects to be transferred 10 during irradiation with a laser beam can be mitigated, and thus the transfer of the objects to be transferred 10 to the second substrate 2 can be controlled. Examples of such organic films include, in addition to polyimide films, organic films such as polymethyl methacrylate, polycarbonate, polyethylene terephthalate, nitrocellulose, polystyrene, poly(α-methylstyrene), and polytetrafluoroethylene.

When an organic film such as a polyimide film is used as an ablation layer, the laser energy density required to ablate the ablation layer tends to be lower than the energy density required when an inorganic film such as a GaN layer is used as the ablation layer. Specifically, the energy density required to ablate a GaN layer is about 1200 to 1600 mJ/cm², while the energy density required to ablate a polyimide film is about 50 to 300 mJ/cm². Therefore, when the shape of the laser beam that the photomask 6 is irradiated with is made into a rectangular shape or a line shape, the length in the longitudinal direction of the laser shape can be increased without changing the length in the short-length direction. Specifically, when trying to obtain a rectangular or line-shaped laser beam with energy density of about 1200 to 1600 mJ/cm², the upper limit of the length in the longitudinal direction is about 30 mm. However, when trying to obtain a rectangular or line-shaped laser beam with the energy density is about 50 to 300 mJ/cm², the length in the longitudinal direction can be increased to about 90 mm. Therefore, by using a laser beam having such a long length in the longitudinal direction, it is possible to apply laser lift-off to a large number of objects to be transferred 10 at once. Even if occurrence of transfer defects is low at first glance, in such a case where transferring a large number of objects to be transferred 10 at a time, a large number of transfer defects will occur due to many number of objects to be transferred 10. In other words, when transferring a large number of objects to be transferred 10 at once, it is very important to improve the transfer accuracy, and the industrial effects obtained by applying the present invention are very significant.

In examples shown in FIGS. 7 and 11, the energy of the laser beam 20e incident on the portions 11b of the interface 11 in the preliminary irradiation step, is made to be smaller than the energy of the laser beam 20 incident on the portions 11a of the interface 11 in the at-once transfer step, by changing the energy of the laser beam 20d incident on the photomask 130, or output of the laser oscillator 110 shown FIG. 1.

### Second Example

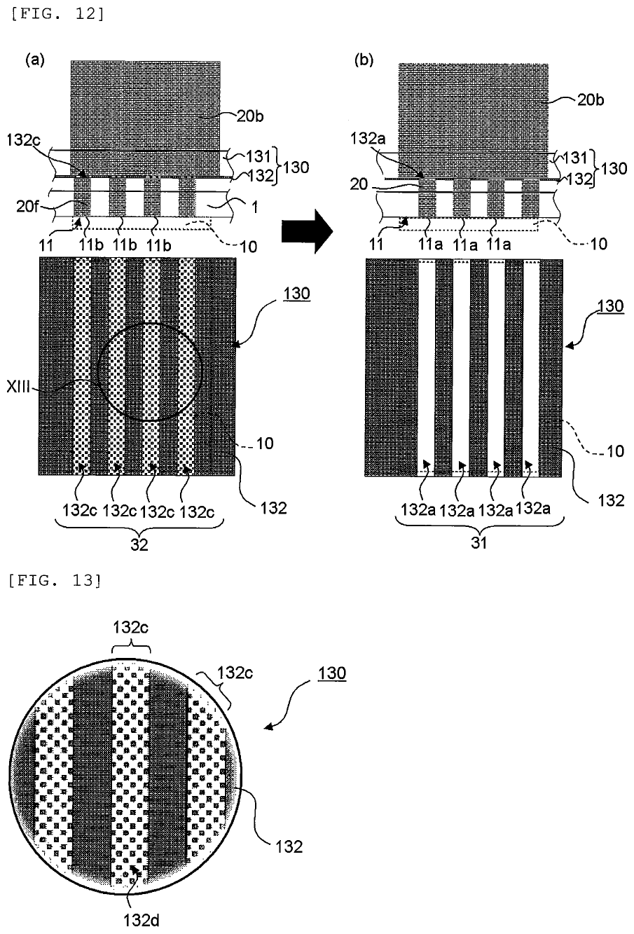

FIG. 12(a) schematically shows the second example of the preliminary irradiation step in an example of the inventive laser lift-off method. FIG. 12(b) shows an example of the at-once transferring step performed after the preliminary irradiation step shown in FIG. 12(a). Further, FIG. 13 shows an enlarged view of a part XIII of the photomask used in FIG. 12.

The second example differs from the first example in that the energy of the laser beam 20b incident on the photomask 130 is not different between the preliminary irradiation step and the at-once transferring step, that is, the laser output of the laser oscillator 110 is not changed, and in terms of a second pattern 32 of the photomask 130 used in the preliminary irradiation step.

The second pattern 32 of the photomask 130 in the second example has a plurality of openings 132c, as shown in FIGS. 12(a) and 13, and has dot-shaped non-opening portions 132d provided in each of the opening portions 132c.

Each of the dot-shaped non-opening portions 132d is smaller than the irradiation wavelength of the laser beam 20b incident on the photomask 130. Therefore, the non-opening portions 132d are not involved in changing the irradiation shape of the laser beam 20b. On the other hand, the laser beam 20b hits the non-opening portions 132d, and thus the energy of the laser beam 20b is attenuated. Therefore, by passing through the second pattern 32 having the non-opening portions 132d of the photomask 130, the laser beam 20b is shaped into the laser beam 20f having a pattern corresponding to the opening portions 132c, which is the same pattern as when the non-opening portions 132d does not exist, and having attenuated energy attenuated, and the laser beam 20f is emitted from the photomask 130. Thus, in the preliminary irradiation step shown in FIG. 12(a), portions 11b of the interface 11 between each of the objects to be transferred 10 and the first substrate 1 can be irradiated with the laser beam 20f having energy that is lower than that of the laser beam 20 emitted in the at-once transferring step shown in FIG. 12(b) and not enough to remove the objects to be transferred 10 from the first substrate 1.

### Third Example

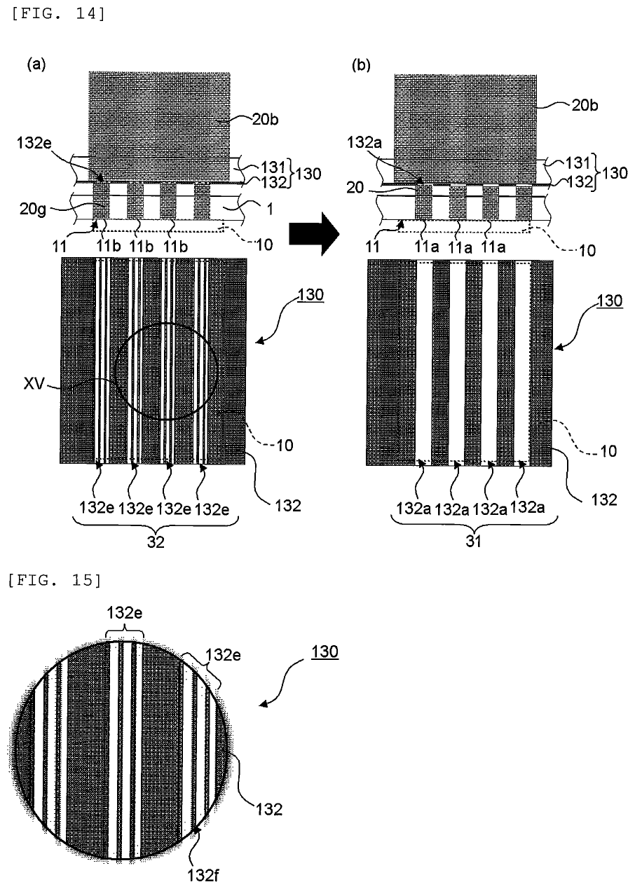

FIG. 14(a) schematically shows the third example of the preliminary irradiation step in an example of the inventive laser lift-off method. FIG. 14(b) shows an example of the at-once transferring step performed after the preliminary irradiation step shown in FIG. 14(a). Further, FIG. 15 shows an enlarged view of a part XV of the photomask used in FIG. 14.

The third example differs from the second example in that each opening 132e in the second pattern 32 of the photomask 130 is provided with striped non-opening portions 132f.

The width of each of the striped non-opening portions 132f is smaller than the irradiation wavelength of the laser beam 20b incident on the photomask 130. Therefore, the non-opening portions 132f are not involved in changing the irradiation shape of the laser beam 20b. On the other hand, the laser beam 20b hits the non-opening portions 132f, and thus the energy of the laser beam 20b is attenuated. Therefore, by passing through the second pattern 32 having the non-opening portions 132f of the photomask 130, the laser beam 20b is shaped into a laser beam 20g having a pattern corresponding to the opening portions 132e, which is the same pattern as when the non-opening portions 132f does not exist, and attenuated energy, the laser beam 20g is emitted from the photomask 130. Thus, in the preliminary irradiation step shown in FIG. 14(a), portions 11b of the interface 11 between each of the objects to be transferred 10 and the first substrate 1 can be irradiated with the laser beam 20g having energy that is lower than that of the laser beam 20 emitted in the at-once transferring step shown in FIG. 14(b) and not enough to remove the objects to be transferred 10 from the first substrate 1.

### Fourth Example

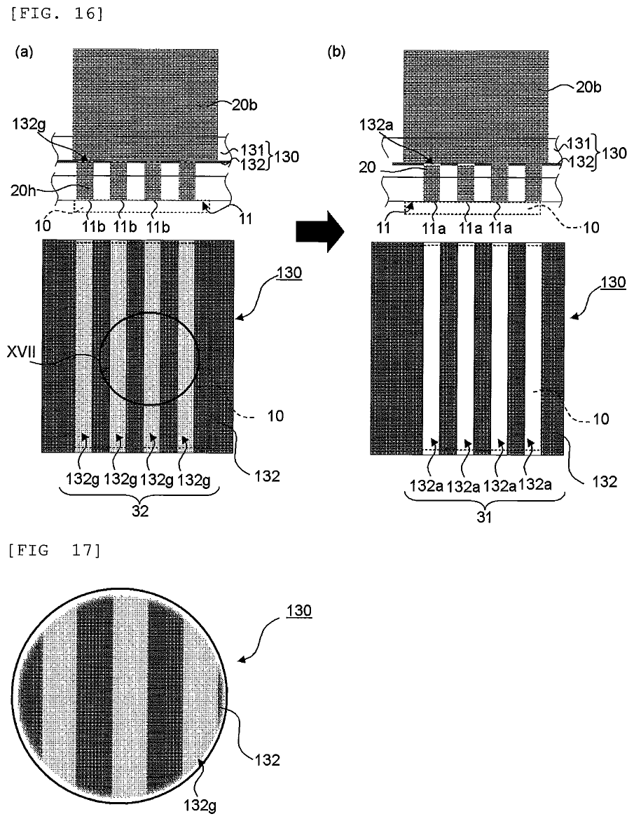

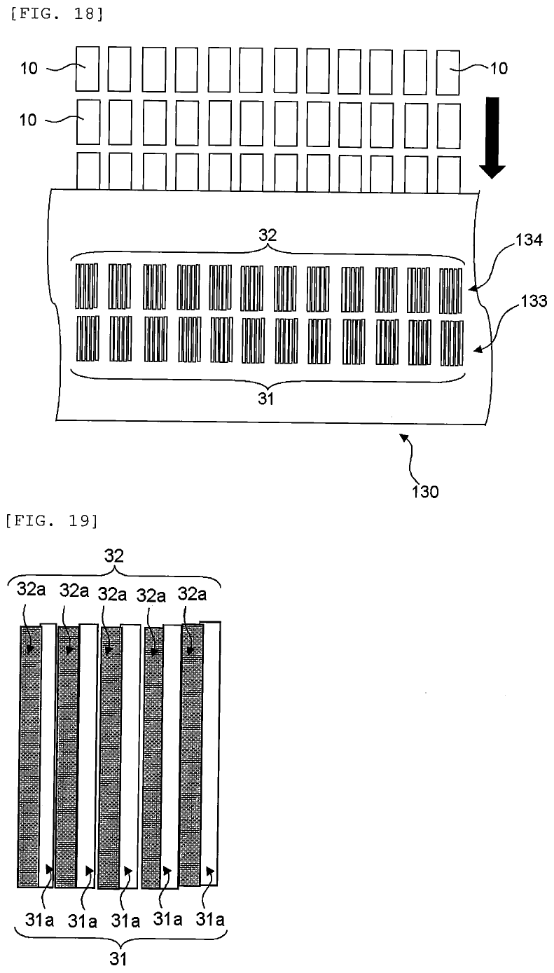

FIG. 16(a) schematically shows the fourth example of the preliminary irradiation step in an example of the inventive laser lift-off method. Further, FIG. 16(b) shows an example of the at-once transferring step performed after the preliminary irradiation step shown in FIG. 16(a). Further, FIG. 17 shows an enlarged view of a part XVII of the photomask used in FIG. 16.

The fourth example differs from the second example in that the second pattern 32 of the photomask 130 includes a plurality of phase shift mask portions 132g.

A part of the components of the laser beam 20b incident on the phase shift mask portions 132g undergoes a 180°-phase shift by passing through a phase shift film included in the phase shift mask portions 132g. The phase-shifted component is 180° out of phase with the component that did not pass through the phase shift film, and thus they counteract each other. As a result, the energy of the laser beam 20b incident on the phase shift mask portions 132 is attenuated. Therefore, by passing through the second pattern 32 having the phase shift mask portions 132g of the photomask 130, the laser beam 20b is shaped into a laser beam 20h having a pattern corresponding to the opening portions 132g and attenuated energy, and the laser beam 20b is emitted from the photomask 130. Thus, in the preliminary irradiation step shown in FIG. 16(a), the portions 11b of the interface 11 between each of the objects to be transferred 10 and the first substrate 1 can be irradiated with the laser beam 20h having energy that is lower than that of the laser beam 20 emitted in the at-once transferring step shown in FIG. 16(b) and not enough to remove the objects to be transferred 10 from the first substrate 1.

In this way, for example, according to the second to fourth examples, in the preliminary irradiation step, the portions 11b of the interface 11 between each of the objects to be transferred 10 and the first substrate 1 can be irradiated with the laser beam having energy that is lower than that of the laser beam 20 emitted in the at-once transferring step performed afterward and not enough to remove the objects to be transferred 10 from the first substrate 1, without changing the output of the laser beam emitted from oscillator 110. It is very advantageous in terms of mass production that the preliminary irradiation step and the at-once transferring step can be performed without changing the output of the laser oscillator 110.

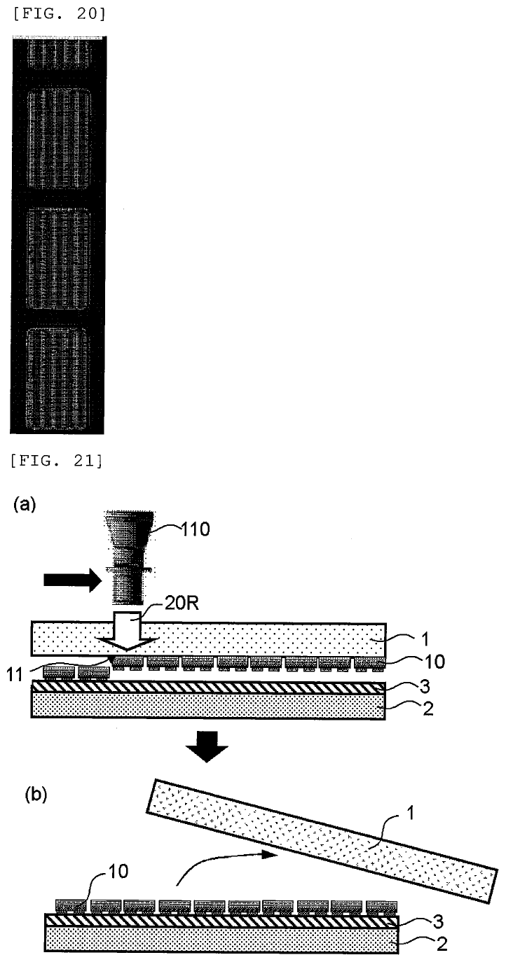

A specific example in which the preliminary irradiation step and the at-once transferring step of the second example, which was described with reference to FIGS. 12 and 13, can be performed will be described with reference to FIGS. 18 and 19.

FIG. 18 is a schematic diagram showing an arrangement example of the photomask 130 that enable to perform the preliminary irradiation step and the at-once transfer step of the second example and the objects to be transferred 10. In FIG. 18, illustration of components other than the photomask 130 and the objects to be transferred 10 is omitted.

The photomask 130 shown in FIG. 18 includes a second portion 134 having a second pattern 32 shown in FIG. 12(a) and a first portion 133 having a first pattern 31 shown in FIG. 12(b).

An arrows in FIG. 18 indicates a moving direction of the objects to be transferred 10. In this example, the photomask 130 and the objects to be transferred 10 are arranged so that the second pattern 32 of the photomask 130 comes above the objects to be transferred 10 before the first pattern 31 does.

In the second pattern 32, a chromium shielding film, which is the pattern-forming layer 132 in which the opening portions 132c and the dot-shaped non-opening portions 132d shown in FIGS. 12(a) and 13 are formed, is formed on a quartz glass which is a base material 131.

The dot-shaped non-opening portions 132d screen 15% of the opening area of each of the opening portions 132c.

On the other hand, in the first pattern 31, a chromium shielding film, which is the pattern forming layer 132 in which the opening portions 132a shown in FIG. 12(b) are formed, are formed on a quartz glass which is a base material 131.

Therefore, the first portion 133 of the photomask 130 has a first laser transmittance, and the second portion 134 has a second laser transmittance that is lower than the first laser transmittance.

Specifically, when the laser lift-off is performed with such an arrangement, the energy (energy density) of the laser beam 20f incident on the portions 11b of the interface 11 between each of the objects to be transferred 10 and the first substrate 1 in the preliminary irradiation step shown in FIG. 12(a) is 15% lower than the energy of the laser beam 20 incident on the portions 11a of the interface 11 between each of the objects to be transferred 10 and the first substrate 1 in the at-once transfer step shown in FIG. 12(b). For example, if the energy incident on the portions 11a of the interface 11 in the at-once transfer step is 1.4 J/cm², the energy of the laser beam 20f incident on the portions 11b of the interface 11 in the preliminary irradiation step is 1.2 J/cm².

When the preliminary irradiation step and the at-once transferring step are performed in the arrangement shown in FIG. 18, for example, as shown in FIG. 19, the second pattern 32 having the plurality of irradiated portions 32a in the preliminary irradiation step and the first pattern 31 having the plurality of irradiation portions 31a in the at-once transferring step are formed to be shifted from each other.

As an example, FIG. 18 shows a photomask 130 having the second pattern 32 shown in FIGS. 12 and 13, but the photomask 130 used in the present invention may have the second pattern 32 in the other example described above, or other second patterns.

The preliminary irradiation step described above can be performed in various forms.

For example, the preliminary irradiation step can be performed, for example, 1 to 4 times.

The number of times to perform the preliminary irradiation steps is not particularly limited, but by performing the preliminary irradiation step once or twice, the speed of the transfer operation by the laser lift-off can be improved. In addition, by performing the preliminary irradiation step three or four times, it becomes easier to control the impact applied to the objects to be transferred during the laser lift-off while keeping an appropriate speed of the transfer operation by the laser lift-off.

For example, in each of the preliminary irradiation step and the at-once transferring step, irradiation with the laser beam is preferably performed so that an irradiated area with the laser beam (for example, the irradiated portions 31a and 32a shown in FIG. 19) is 10 to 60% of an area of the interface 11 between each of the objects to be transferred 10 and the first substrate 1.

When irradiation area by partial irradiation in each of the preliminary irradiation step and the at-once transferring step is within the range of 10 to 60% of the area of the interface 11 between each of the objects to be transferred 10 and the first substrate 1, it is possible to efficiently transfer the objects to be transferred from the first substrate to the second substrate and give a margin for irradiation error of the laser beam.

Further, the irradiated areas with the laser beam are preferably set to be different between the preliminary irradiation step and the at-once transferring step.

By changing the laser irradiated area between the preliminary irradiation step and the at-once transfer step, for example, as described with reference to FIG. 11, it is possible to prevent occurrence of the cleavage as shown in FIG. 10 when a material having a crystal structure such as a GaN layer as an ablation layer is used.

In addition, the irradiation in the preliminary irradiation step and the at-once transferring step are performed so that the irradiated areas do not overlap each other, or so that overlapping of the irradiated areas is 10% or less of the area of the interface 11 between each of the objects to be transferred 10 and the first substrate 1.

The irradiation areas in the preliminary irradiation step and the at-once transfer step may overlap each other, and by making the overlapping more than 0% and less than 10%, it is possible to have a margin for irradiation error with the laser beam.

For example, by arranging the opening portions in the first portion 133 and the second portion 134 of the photomask 130 in a matrix, the degree to which the irradiation areas overlap each other can be easily controlled.

In addition, when laser-irradiated portion or non-irradiated portions has a line shape, as shown in FIG. 4, FIGS. 5(c) and (d), and FIGS. 6(c) and (d), it is preferable that laser-irradiated portion or non-irradiated portions are arranged at intervals equal to or greater than the width in the short-length directions of these portions. By such arrangement, the degree of overlapping of the irradiated portions can be easily controlled.

In addition, as a total sum of the preliminary irradiation step and the at-once transferring step, the irradiated areas with the laser beam can be 40 to 100% of an area of the interface 11 between each of the objects to be transferred 10 and the first substrate 1.

By virtue of irradiating 40% or more of the area of the interface 11 between each of the objects to be transferred 10 and the first substrate 1 with the laser beam as a total sum of the preliminary irradiation step and the at-once transferring step, the transfer can be performed more efficiently. If it is the sum of the preliminary irradiation step and the at-once transferring step, the entire area, or 100% of the interface 11 between each of the objects to be transferred 10 and the first substrate 1 may be irradiated with the laser beam.

It is particularly preferable that the inventive laser lift-off apparatus is configured to be able to perform the preliminary irradiation step described above.

For example, the inventive laser lift-off apparatus 100 can be further configured to be able to switch energy of the laser beam for irradiating the interfaces 11 between the objects to be transferred 10 and the first substrate 1, between energy not enough to remove the objects to be transferred 10 from the first substrate 1 and energy enough to remove the objects to be transferred 10 from the first substrate 1, as the first example described with reference to FIG. 7.

Alternatively, in the laser lift-off apparatus 100, the pattern of the photomask can include the first pattern 31 and the second pattern 32 as the second to fourth examples described with reference to FIGS. 12 to 17, and the laser lift-off apparatus can be configured: so as to be able to irradiate the interfaces 11 between the objects to be transferred 10 and the first substrate 1 with the laser beam 20 through the first pattern 31 at once at the energy enough to remove the objects to be transferred 10 from the first substrate 1; and so as to be able to irradiate the interfaces 11 between the objects to be transferred 10 and the first substrate 1 with the laser beam through the second pattern 32 at once at the energy not enough to remove the objects to be transferred 10 from the first substrate 1. The laser lift-off apparatus 100 having such aspects is very advantageous in terms of mass production

### [Objects to be Transferred]

Objects to be transferred of the present invention are not particularly limited. For example, as objects to be transferred, it is possible to transfer objects selected from the group consisting of semiconductor chips, LED chips, resin material films, and inorganic films. The resin material film may contain an inorganic material. Further, the resin material film may have a multilayer structure, and a plurality of films constituting the multilayer structure may be made of only a resin material film, or may be made of a combination of a resin material film and an inorganic material film.

When the thin objects to be transferred with a thickness of 1 to 10 μm are subjected to the full-surface irradiation according to a normal laser lift-off method, the more a longitudinal dimension of the objects to be transferred or an area of the objects to be transferred is, the easier the objects to be transferred is damaged during the laser lift-off. Specifically, in the case of objects to be transferred with a longitudinal dimension of 80 μm or more, or objects to be transferred with an area of 6400 μm² or more, the objects to be transferred are easily broken during the laser lift-off performing full-surface irradiation. Therefore, it is effective to apply the present invention, which can reduce propulsion force applied to the objects to be transferred. The upper limits of the longitudinal dimension and the area are not particularly limited, but from a viewpoint of ease of production, they are approximately 500 μm or less and 40000 μm² or less, respectively.

### [Method for Manufacturing a Receptor Substrate]

The laser lift-off method of the present invention described above can be applied to, for example, a method for manufacturing a receptor substrate.

For example, when it is a method for manufacturing a receptor substrate provided with objects to be transferred, the method comprising: a step of providing a donor substrate provided with the objects to be transferred and a receptor precursor substrate; and a step of obtaining the receptor substrate by transferring the objects to be transferred from the donor substrate onto the receptor precursor substrate by virtue of laser lift-off, wherein in the step of obtaining the receptor substrate, by virtue of the inventive laser lift-off method, the objects to be transferred are subjected to the laser lift-off from the donor substrate as the first substrate onto the receptor precursor substrate as the second substrate, as a receptor substrate is obtained by transferring objects to be transferred according to the inventive laser lift-off method, it is possible to manufacture a receptor substrate provided with objects to be transferred without positional deviation thereof or damage.

The inventive method for manufacturing a receptor substrate is an example of the application of the inventive laser lift-off method, and the application of the inventive laser lift-off method is not limited thereto.

### [Photomask]

The inventive photomask is a photomask that can be used in the laser lift-off method of the present invention described above. Therefore, the inventive photomask encompasses all the aspects of the photomask 130 described above.

For example, a photomask of the first aspect of the present invention is a photomask used in a laser lift-off method in which the objects to be transferred 10 are transferred by virtue of laser lift-off from the first substrate 1 provided with the objects to be transferred onto the second substrate 2, wherein the photomask is configured so that the interface 11 between each of the objects 10 to be transferred and the first substrate 1 is irradiated at once with a received laser beam, and the photomask has a pattern 31 to shape the laser beam so that only a portion 11a of the interface 1 between each of the objects 10 to be transferred and the first substrate 1 is to be an irradiated portion.

As described above, the pattern 31 of the photomask 130 may shape the laser beam so that a plurality of laser-irradiated portions are formed or may shape the laser beam so that a plurality of non-irradiated portions where the laser beam is not irradiated are formed on the interface 11 between each of the objects 10 to be transferred and the first substrate 1.

Further, for example, with using the photomask having a first part 133 having the pattern (a first pattern) 31 formed and a first laser transmissivity and a second part 134 having a second laser transmissivity being lower than the first laser transmissivity, it is possible to perform the preliminary irradiation step and the at-once transferring step described before without changing laser output of the laser oscillator 110.

Expressing such a photomask 130 from another aspect, the photomask of the present invention in a second aspect can be said that the photomask 130 used in a laser lift-off method in which objects to be transferred 10 are transferred by virtue of laser lift-off from a first substrate provided with the objects to be transferred 10 onto a second substrate, comprising:
a first part 133 having a pattern 31 for shaping a shape of a received laser beam into a patterned shape and a first laser transmissivity, and
a second part 134 having a second laser transmissivity being lower than that of the first laser transmissivity.

By performing the inventive laser lift-off method using the inventive photomask 130, it is possible to prevent occurrence of damage to the objects to be transferred without positional deviation of objects to be transferred during the transfer. Note that, the inventive laser lift-off method can be performed without using the inventive photomask 130.

### EXAMPLES

Hereinafter, the present invention will be specifically described with reference to Examples and Comparative Examples. However, the present invention is not limited thereto.

### Example 1

A sapphire substrate provided with 1.5 million LED chips as objects to be transferred was provided as the first substrate. The size of the LED chip was 40 μm×60 μm.

Further, a quartz substrate having a silicone rubber layer as an adhesive layer on its surface was provided as the second substrate.

In Example 1, a total of 1.5 million LED chips were transferred from the first substrate to the second substrate according to the Contact-LLO method using the laser lift-off apparatus shown in FIG. 2.

In Example 1, a preliminary irradiation step and an at-once transfer step were performed using the photomask 130 described with reference to FIGS. 12, 13, and 18.

Specifically, in this Example, as shown in FIG. 18, objects to be transferred are moved relative to the photomask in the direction of the arrow. Therefore, in practice, laser lift-off is performed in the following order.
(i) The preliminary irradiation step for a lower row
(ii) The at-once transferring step for the lower row and the preliminary irradiation step for an upper row
(iii) The at-once transferring step for the upper row and the preliminary irradiation step for a next row above the upper row
(iv) The at-once transferring step for the next row above the upper row and the preliminary irradiation step for two rows above the upper row

Of course, the preliminary irradiation step and the at-once transferring step may be completed for each specific area, for example, the preliminary irradiation step and the at-once transferring step for each row may be completed, and then the preliminary irradiation step and the at-once transferring step for another area may be performed.

Further, after the preliminary irradiation step is performed on all LED chips, the at-once transferring step for all LED chips may be performed. Here, the preliminary irradiation step for all LED chips may be performed in a single step, or the preliminary irradiation steps may be performed also respectively for each of divided specific areas. Further, the at-once transferring step for all LED chips may be performed in a single step, or the at-once transferring steps may be performed also respectively for each of divided specific areas.

The first pattern 31 and the second pattern 32 of the photomask 130 were made with a line to space ratio of 1:1 with 8 μm each.

In the preliminary irradiation step, the energy (energy density) of the laser beam 20f incident on portions 11b of the interface 11 between each of the objects 10 to be transferred and the first substrate 1 was set to 1.2 J/cm².

Thereafter, the photomask 130 was moved by 8 μm in the direction of the arrow shown in FIG. 18 and then the at-once transferring step was performed.

In the at-once transferring step, the energy (energy density) of the laser beam 20 incident on portions 11b of the interface 11 between each of the objects 10 to be transferred and the first substrate 1 was set to 1.4 J/cm².

### Example 2

In Example 2, a total of 1.5 million LED chips were transferred from a first substrate onto a second substrate in the same manner as Example 1 except that the preliminary irradiation step was not performed.

### Comparative Example

In Comparative Example, a total of 1.5 million LED chips were transferred from a first substrate onto a second substrate in the same manner as Example 2 except that the entire surface of the interfaces 11 between each of the objects 10 to be transferred and the first substrate 1 were irradiated with the laser beam in the at-once transfer step.

The LED chips transferred to the second substrate in Examples 1 and 2 were checked, and the results thereof showed that the positional accuracy of the LED chips was high and no major damage to the LED chips was confirmed.

On the other hand, in Comparative Example, it was confirmed that 10% of the LED chips transferred to the second substrate were damaged.

A photograph of the first substrate after the transfer in Example 1 is shown in FIG. 20. As is clear from FIG. 20, almost no residue was observed on the first substrate after the transfer in Example 1.

On the other hand, FIG. 9 is a photograph of the first substrate after the transfer in Example 2. As is clear from FIG. 9, some residues were observed on the first substrate after the transfer in Example 2. Note that, the residue was observed as a black residue due to the light used in the microscope in this evaluation.

Note that, in the embodiment described above, an example in which LED chips having a GaN layer as objects to be transferred is subjected to the lift-off from a sapphire substrate as a first substrate was described. However, the present invention is not limited to this embodiment. Specifically, it is also applicable to a case in which resin material film or inorganic film in a chip-shape or the like, microscopic device, or chip, provided on a first substrate with a sapphire substrate or a glass substrate as base material is transferred onto a second substrate. Furthermore, it is also applicable to a case in which objects to be transferred that are adhered via an ablation layer are transferred from a first substrate having the ablation layer such as a polyimide film formed on its surface onto a second substrate.

Further, the present invention is not limited to the above-described embodiments. The above embodiments are just examples, and any examples that have substantially the same feature and demonstrate the same functions and effects as those in the technical concept disclosed in claims of the present invention are included in the technical scope of the present invention.

1-25. (canceled)

26. A laser lift-off apparatus for transferring objects to be transferred from a first substrate provided with the objects to be transferred onto a second substrate by virtue of laser lift-off, the apparatus comprising:
a laser oscillator;
a stage for supporting the first substrate and the second substrate while facing each other; and
a photomask provided in an optical path between the laser oscillator and the stage,
wherein the laser oscillator, the photomask, and the stage are configured to irradiate interfaces between the objects to be transferred and the first substrate with a laser beam from the laser oscillator at once, and
the photomask has a pattern for shaping a laser beam from the laser oscillator into such a shape that only a portion of an interface between each of the objects to be transferred and the first substrate is irradiated with the laser beam.

27. The laser lift-off apparatus according to claim 26, wherein the laser lift-off apparatus is further configured to switch energy for irradiating the interfaces between the objects to be transferred and the first substrate with the laser beam, between energy not enough to remove the objects to be transferred from the first substrate and energy enough to remove the objects to be transferred from the first substrate.

28. The laser lift-off apparatus according to claim 27, wherein the pattern of the photomask includes a first pattern and a second pattern, and
the laser lift-off apparatus is configured:
so as to be able to irradiate interfaces between the objects to be transferred and the first substrate with the laser beam through the first pattern at once at the energy enough to remove the objects to be transferred from the first substrate; and
so as to be able to irradiate interfaces between the objects to be transferred and the first substrate with the laser beam through the second pattern at once at the energy not enough to remove the objects to be transferred from the first substrate.

29. A photomask used in a laser lift-off method in which objects to be transferred are transferred by virtue of laser lift-off from a first substrate provided with the objects to be transferred onto a second substrate, wherein
the photomask is configured so that an interface between each of the objects to be transferred and the first substrate is irradiated at once with a received laser beam, and
the photomask has a pattern to shape the laser beam so that only a portion of the interface between each of the objects to be transferred and the first substrate is to be an irradiated portion.

30. The photomask according to claim 29, wherein the pattern is a pattern for shaping the laser beam so that the laser-irradiated portions are formed plurally.

31. The photomask according to claim 29, wherein the pattern is a pattern for shaping the laser beam so that non-irradiated portions where irradiation with the laser beam is not performed are formed plurally in the interface between each of the objects to be transferred and the first substrate.

32. The photomask according to claim 29, wherein the photomask has:
a first part on which the pattern is formed and which has a first laser transmissivity; and
a second part having a second laser transmissivity being lower than the first laser transmissivity.

33. A photomask used in a laser lift-off method in which objects to be transferred are transferred by virtue of laser lift-off from a first substrate provided with the objects to be transferred onto a second substrate, comprising:
a first part having a pattern formed for shaping a received laser beam into a patterned shape and a first laser transmissivity; and
a second part having a second laser transmissivity being lower than the first laser transmissivity.

34. A transferring apparatus for transferring objects to be transferred from a first substrate provided with the objects to be transferred onto a second substrate by virtue of laser, the apparatus comprising:
a laser oscillator;
a stage for supporting the first substrate and the second substrate while facing each other; and
a photomask provided in an optical path between the laser oscillator and the stage,
wherein the laser oscillator, the photomask, and the stage are configured to irradiate interfaces between the objects to be transferred and the first substrate with a laser beam from the laser oscillator at once, and
the photomask has a pattern for shaping a laser beam from the laser oscillator into such a shape that only a portion of an interface between each of the objects to be transferred and the first substrate is irradiated with the laser beam.

35. The transferring apparatus according to claim 34, wherein the transferring apparatus is further configured to switch energy for irradiating the interfaces between the objects to be transferred and the first substrate with the laser beam, between energy not enough to remove the objects to be transferred from the first substrate and energy enough to remove the objects to be transferred from the first substrate.

36. The transferring apparatus according to claim 35, wherein the pattern of the photomask includes a first pattern and a second pattern, and
the transferring apparatus is configured:
so as to be able to irradiate interfaces between the objects to be transferred and the first substrate with the laser beam through the first pattern at once at the energy enough to remove the objects to be transferred from the first substrate; and
so as to be able to irradiate interfaces between the objects to be transferred and the first substrate with the laser beam through the second pattern at once at the energy not enough to remove the objects to be transferred from the first substrate.

37. A photomask used in a transferring method in which objects to be transferred are transferred by virtue of laser from a first substrate provided with the objects to be transferred onto a second substrate, wherein
the photomask is configured so that an interface between each of the objects to be transferred and the first substrate is irradiated at once with a received laser beam, and
the photomask has a pattern to shape the laser beam so that only a portion of the interface between each of the objects to be transferred and the first substrate is to be an irradiated portion.

38. The photomask according to claim 37, wherein the pattern is a pattern for shaping the laser beam so that the laser-irradiated portions are formed plurally.

39. The photomask according to claim 37, wherein the pattern is a pattern for shaping the laser beam so that non-irradiated portions where irradiation with the laser beam is not performed are formed plurally in the interface between each of the objects to be transferred and the first substrate.

40. The photomask according to claim 37, wherein the photomask has:
a first part on which the pattern is formed and which has a first laser transmissivity; and
a second part having a second laser transmissivity being lower than the first laser transmissivity.

41. A photomask used in a transferring method in which objects to be transferred are transferred by virtue of laser from a first substrate provided with the objects to be transferred onto a second substrate, comprising:
a first part having a pattern formed for shaping a received laser beam into a patterned shape and a first laser transmissivity; and
a second part having a second laser transmissivity being lower than the first laser transmissivity.
